(19) United States
(12) Patent Application Publication
(10) Pub. No.: US 2006/0057783 A1
(43) Pub. Date: Mar. 16, 2006

(54) Methods of forming fuses using selective etching of capping layers

(76) Inventors: Cheol-ju Yun, Gyeonggi-do (KR); Bo-sung Kim, Gyeonggi-do (KR); Huck-jin Kang, Seoul (KR)

Correspondence Address: MYERS BIGEL SIBLEY & SAJOVEC, PO BOX 37428, RALEIGH, NC, 27627, US

(21) Appl. No.: 11/225,789

(22) Filed: Sep. 13, 2005

(30) Foreign Application Priority Data
Sep. 13, 2004 (KR) 10-2004-0073123

(51) Int. Cl. H01L 21/82

(52) U.S. Cl. 438/128

(57) ABSTRACT

A method of forming a fuse in a semiconductor device can be provided by selectively removing an inter-metal insulator to expose a fuse capping layer by recessing the inter-metal insulator around the fuse and removing the capping layer from the fuse to expose a fuse metal film thereunder.

### CROSS-REFERENCE TO RELATED APPLICATION

This application claims the benefit of Korean Patent Application No. 10-2004-0073123, filed on Sep. 13, 2004, in the Korean Intellectual Property Office, the disclosure of which is incorporated herein in its entirety by reference.

### FIELD OF THE INVENTION

The present invention relates to methods of forming semiconductor devices, and more particularly, to methods of forming fuses in semiconductor memory devices.

### BACKGROUND

In general, when a semiconductor device, in particular, a semiconductor memory device has at least one malfunctioning cell, the semiconductor memory devices may malfunction and are therefore discarded. The discarding effectively reduces yield, and is therefore, a source of inefficiency, since there is a much larger number of defect-free cells in the semiconductor memory device. Therefore, in order to increase the yield, redundant memory cells can be included in memory devices to render the entire memory useable by replacing the malfunctioning cells with operative cells. In this case, before the replacing malfunctioning cells with the redundant memory cells, the malfunctioning cells can be electrically separated from the remaining cells. For the separation, a fuse connected to the malfunctioning cells may be cut using a laser beam. Generally, a metal interconnection layer formed in a top portion of a multi-layer interconnection structure is used as a fuse, so that an additional fuse may not be required.

FIGS. 1 and 2 are sectional views illustrating a conventional method of forming a fuse in a semiconductor device. Referring to FIG. 1, upper interconnection layer patterns 110a, 110b, and 110c are formed on a first inter-metal insulator 100 that covers a lower interconnection layer (not shown). The upper interconnection layer patterns 110a, 110b, and 110c are formed by sequentially depositing a barrier metal layer pattern 112, a metal film pattern 114, and a capping layer pattern 116 on the first inter-metal insulator 100. A second inter-metal insulator 120 completely covering the upper interconnection layer patterns 110a, 110b, and 110c is formed. A mask film pattern 130 is formed on the second inter-metal insulator 120. The mask film pattern 130 has an opening 140 exposing a fuse opening region.

Referring to FIG. 2, the second inter-metal insulator 120 and the capping layer pattern 116 are dry etched using the mask film pattern 130 as an etch mask. In this case, the capping layer pattern 116 is over-etched to ensure that the capping layer pattern 116 is removed. At this time, the second inter-metal insulator 120 is also over-etched. As a result, the metal film pattern 114 protrudes a height d1 from the second inter-metal insulator 120.

FIG. 3 is a sectional view illustrating a problem that occurs when the fuse shown in FIG. 2 is cut. Referring to FIG. 3, when laser cutting 150 is performed on the upper interconnection layer pattern 110a, a fragment 160 and the like can be produced. The fragment 160 may cause a short-circuit between the adjacent upper interconnection patterns 110b and 110c.

### SUMMARY

Embodiments according to the invention can provide methods of forming fuses using selective etching of capping layers. Pursuant to these embodiments, a method of forming a fuse in a semiconductor device can include selectively removing an inter-metal insulator to expose a fuse capping layer by recessing the inter-metal insulator around the fuse and removing the capping layer from the fuse to expose a fuse metal film thereunder. In some embodiments according to the invention, selectively removing an inter-metal insulator to expose a fuse capping layer by recessing the inter-metal insulator around the fuse further includes selectively removing the inter-metal insulator to expose the fuse capping layer so that the capping layer protrudes from the inter-metal insulator around the fuse.

In some embodiments according to the invention, selectively removing includes selectively dry-etching the inter-metal insulator relative the capping layer. In some embodiments according to the invention, removing the capping layer includes selectively wet-etching the capping layer relative to the inter-metal insulator around the fuse. In some embodiments according to the invention, selectively wet-etching the capping layer relative to the inter-metal insulator around the fuse includes selectively wet-etching the capping layer relative to the inter-metal insulator around the fuse to recess the fuse to beneath a surface of the inter-metal insulator around the fuse by about 1000 Angstroms.

In some embodiments according to the invention, the inter-metal insulator is an oxide and the capping layer comprises Ti, TiN, and/or Ti/TiN. In some embodiments according to the invention, selectively wet-etching includes wet-etching using an etching solution of H₂O₂ or a mixture of H₂O₂ and water In some embodiments according to the invention, the capping layer is Ti/TiN and a metal film thereunder comprises Al.

In some embodiments according to the invention, selectively wet-etching the capping layer relative to the inter-metal insulator around the fuse further includes wet-etching using a solution of H₂O₂ at about 60 degrees Centigrade for about 11 minutes. In some embodiments according to the invention, the solution of H₂O₂ further includes a chemical solution that avoids etching of Ti and TiN. In some embodiments according to the invention, removing the capping layer from the fuse to expose a fuse metal film thereunder further includes wet-etching the capping layer to recess the fuse beneath a surface of the inter-metal insulator around the fuse to level sufficient to avoid contamination other fuses with debris from a laser cut of the fuse.

In some embodiments according to the invention, a method of forming a fuse in a semiconductor device can be provided by selectively dry-etching an inter-metal insulator to expose a fuse capping layer by recessing the inter-metal insulator around the fuse and selectively wet-etching the capping layer relative to the inter-metal insulator around the fuse to recess the fuse to beneath a surface of the inter-metal insulator around the fuse by about 1000 Angstroms using an etching solution comprising H₂O₂ or a mixture of H₂O₂ and water.

### BRIEF DESCRIPTION OF THE DRAWINGS

FIGS. 1 and 2 are sectional views illustrating a conventional method of forming a fuse in a semiconductor device;

FIG. 3 is a sectional view illustrating a problem that may occur when the fuse shown in FIG. 2 is cut;

FIGS. 4 through 7 are sectional views illustrating methods of forming a fuse in a semiconductor device according to some embodiments of the present invention;

FIGS. 8 and 9 are graphs illustrating the dry etching rates of a capping layer shown in FIG. 5 of a Ti film and a TiN film, respectively;

FIG. 10 is a view of a metal film pattern before over-etching is performed on the capping layer shown in FIG. 5; and

FIG. 11 is a view of a metal film pattern after over-etching is performed on the capping layer shown in FIG. 5.

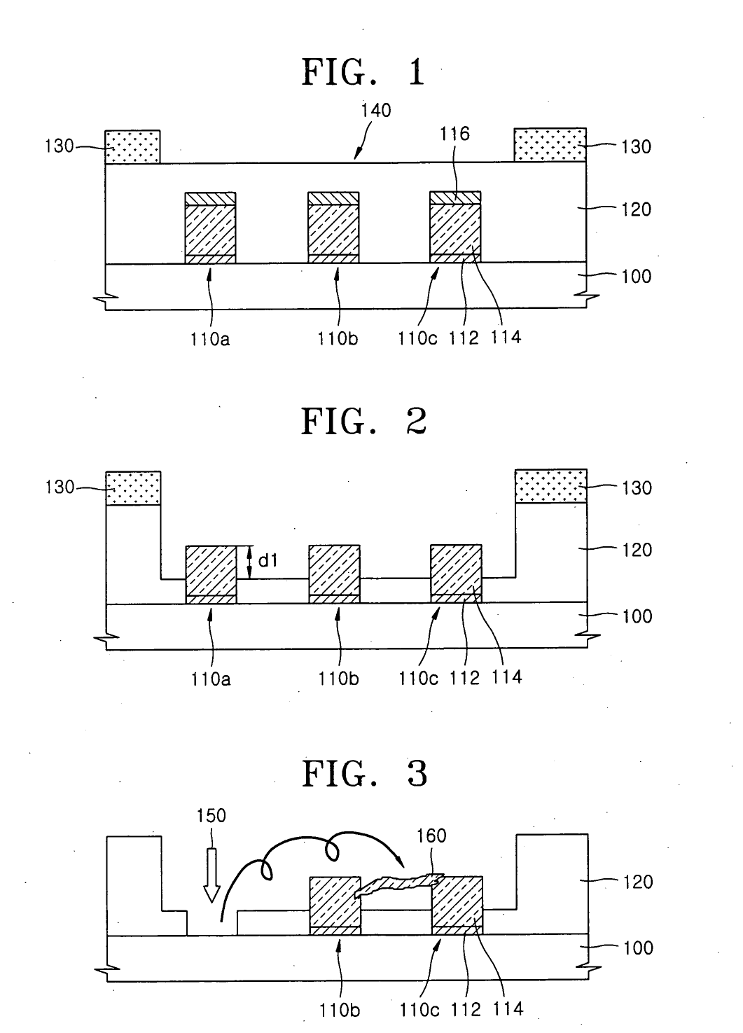

### DESCRIPTION OF EMBODIMENTS ACCORDING TO THE INVENTION

The invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. As used herein the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Furthermore, relative terms, such as “lower”, “bottom”, “upper”, “top”, “beneath”, “above”, and the like are used herein to describe one element's relationship to another elements as illustrated in the Figures. It will be understood that relative terms are intended to encompass different orientations of the subject in the figures in addition to the orientation depicted in the Figures. For example, if the subject in the Figures is turned over, elements described as being on the “lower” side of or “below” other elements would then be oriented on “upper” sides of (or “above”) the other elements. The exemplary term “lower”, can therefore, encompasses both an orientation of “lower” and “upper,” depending of the particular orientation of the figure. Similarly, if the subject in one of the figures is turned over, elements described as “below” or “beneath” other elements would then be oriented “above” the other elements. The exemplary terms “below” or “beneath” can, therefore, encompass both an orientation of above and below.

Embodiments of the present invention are described herein with reference to cross-section (and/or plan view) illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an etched region illustrated or described as a rectangle will, typically, have rounded or curved features. Thus, the regions illustrated in the figures are schematic in nature and their shapes are not intended to illustrate the precise shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. It will also be appreciated by those of skill in the art that references to a structure or feature that is disposed “adjacent” another feature may have portions that overlap or underlie the adjacent feature.

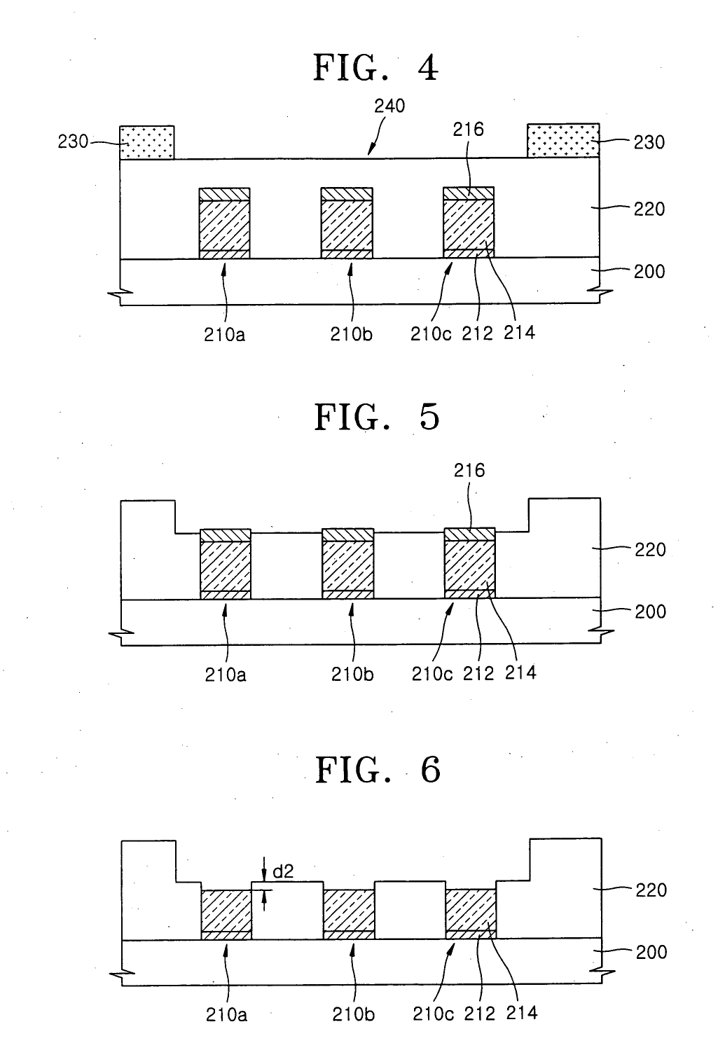

FIGS. 4 through 7 are sectional views illustrating a method of forming a fuse in a semiconductor device according to an embodiment of the present invention. Referring to FIG. 4, upper interconnection layer patterns 210a, 210b, and 210c are formed on a first inter-metal insulator 200 that covers a lower interconnection layer (not shown). The upper interconnection layer patterns 210a, 210b, and 210c function as a fuse. Although only three upper interconnection layer patterns are described in the present invention, more upper interconnection layer patterns can be formed. The upper interconnection layer patterns 210a, 210b, and 210c are electrically connected to the lower interconnection layer (not shown) by a via contact (not shown) penetrating the first inter-metal insulator 200.

The upper interconnection layer patterns 210a, 210b, and 210c each are formed by sequentially depositing a barrier metal layer pattern 212, a metal film pattern 214, and a capping layer pattern 216. In some embodiments according to the invention, the barrier metal layer pattern 212 and the capping layer pattern 216 may be Ti, TiN, or Ti/TiN. The metal film pattern 214 may be Al. Then, a second inter-metal insulator 220 covering the upper interconnection layer patterns 210a, 210b, and 210c is formed. The second inter-metal insulator 220 may be an oxide. Then, a mask film pattern 230 is formed on the second inter-metal insulator 220. The mask film pattern 230 has an opening 240 to expose a fuse opening region. In some embodiments according to the invention, the mask film pattern 230 may be a photoresist film pattern.

Subsequently, referring to FIG. 5, the second inter-metal insulator 220 is dry etched to expose an upper surface of the capping layer pattern 216. The second inter-metal insulator 220 is over-etched to ensure that the upper surfaces of all of the capping layer patterns 216 on a wafer are exposed. As a result, the capping layer pattern 216 can protrude from an upper surface of the second inter-metal insulator 220. After the etching process, the mask film pattern 230 is removed.

Referring to FIG. 6, the capping layer pattern 216 is selectively wet etched (relative to the second inter-metal insulator 220) to expose an upper surface of the metal film pattern 214. When the capping layer pattern 216 is Ti/TiN, a solution for the wet etching may be only H₂O₂ or a solution containing H₂O₂ and another substances. For example, the solution for the wet etching may be composed of H₂O₂ and water. In the wet etching process, when over-etching is performed to remove all of the capping layer patterns 216 on the wafer, an upper surface of the second inter-metal insulator 220 may not be disposed below an upper surface of the exposed metal film pattern 214 due to sufficient wet etch selectivity of the capping layer pattern 216 with respect to the second inter-metal insulator 220. Rather, the upper surface of the metal film pattern 214 is disposed a distance d2 below the upper surface of the second inter-metal insulator 220. The over-etching can be performed by wet-etching.

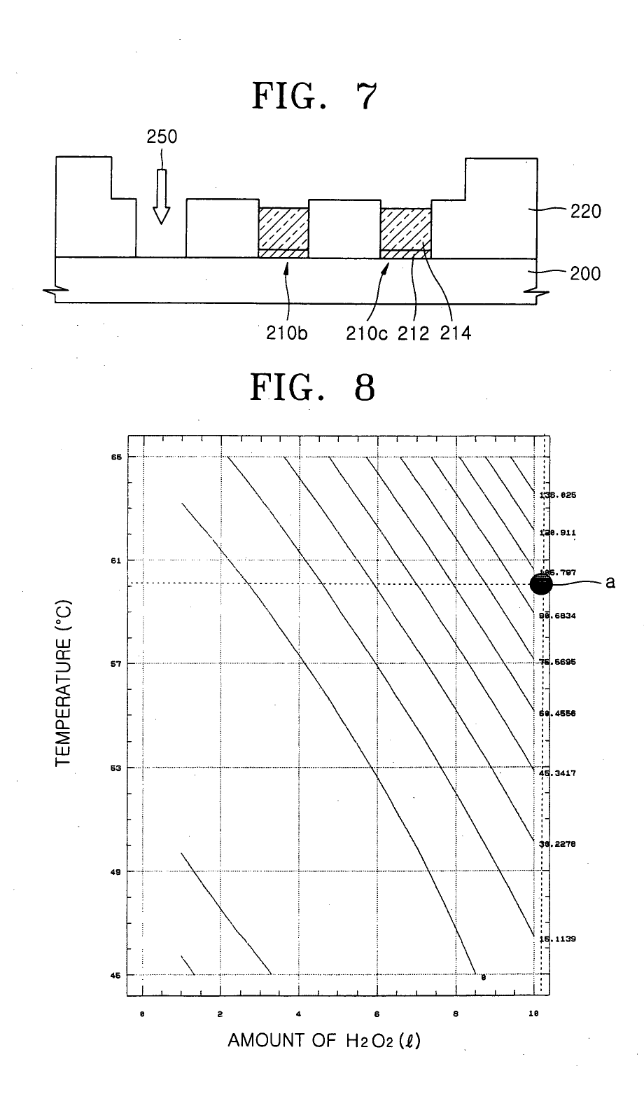

In a semiconductor including a fuse formed using the above method, laser cutting 250 in FIG. 7 is performed to electrically cut malfunctioning cells. The laser cutting 250 will be described in detail with reference to FIG. 7. Referring to FIG. 7, the laser cutting is performed on, for example, the upper interconnection layer pattern 210a in FIG. 6. At this time, fragments or the like can be generated. However, an electric short-circuit between the adjacent upper interconnection layer patterns 210b and 210c due to the fragments can be suppressed because the second inter-metal insulator 220 having a sufficient height is interposed between the upper interconnection layer patterns 210b and 210c.

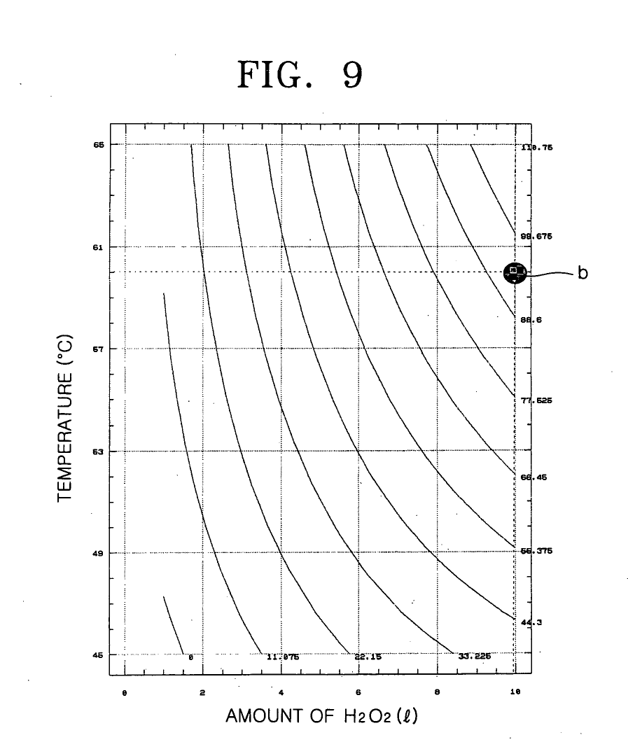

FIGS. 8 and 9 are graphs illustrating wet etching rates of the capping layer pattern 216 composed of a Ti film and a TiN film shown in FIG. 5, respectively. Referring to FIGS. 8 and 9, the x-axis represents the amount of H₂O₂ supplied and the y-axis represents the temperature. In FIG. 8, slant lines represent etching rates of the Ti film. In FIG. 9, slant lines represent etching rates of the TiN film. The etching rates are, as described with reference to FIG. 6, measured when the upper interconnection layer patterns 210a, 210b, and 210c are wet etched to remove the capping layer pattern 216 in an about 20 l bath.

Referring to FIGS. 8 and 9, 10 l of H₂O₂ are added to a chemical solution that cannot etch Ti and TiN in a 20 l bath. In this case, the volume ratio of H202 to the chemical solution is 1:1. Then, the wet etching is performed at about 60 degrees Centigrade using the resulting solution. As a result, etching rates of the Ti film and the TiN film are about 95 Angstroms/min. The wet etching is performed for about 11 minutes on a Ti/TiN capping layer pattern 216, thus removing the Ti/TiN capping layer pattern 216 having a thickness of 1000 Angstroms. At this time, the second inter-metal insulator 220 composed of an oxide is hardly etched.

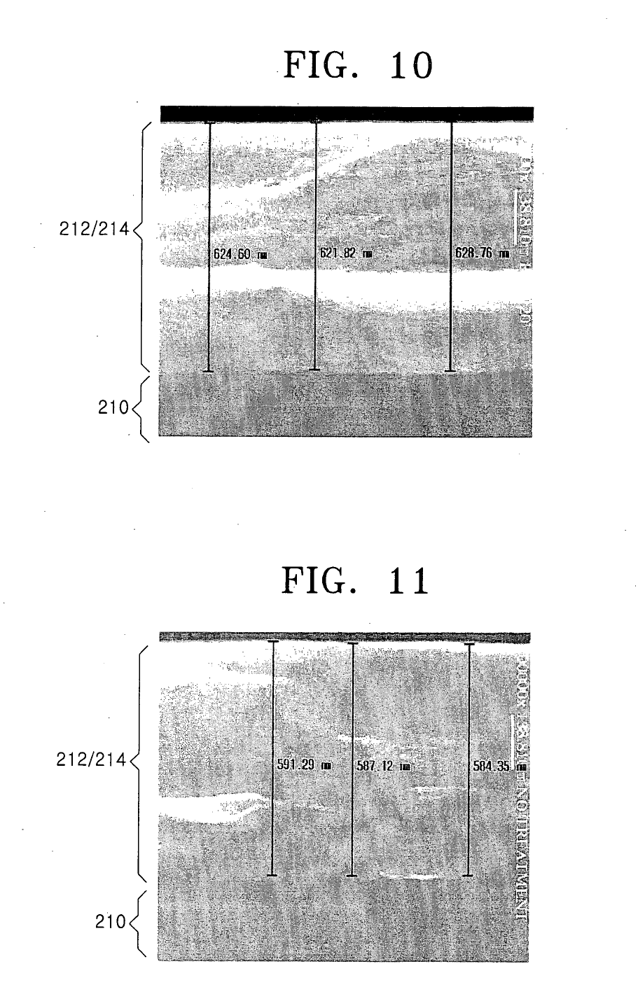

FIG. 10 is a SEM image of a metal film pattern before over-etching is performed on the capping layer pattern 216. FIG. 11 is a SEM image of a metal film pattern after over-etching is performed on the capping layer pattern 216. Referring to FIGS. 10 and 11, as described with reference to FIG. 6, in the wet etching process for removing the capping layer pattern 216, over-etching must be performed to remove all of the capping layer patterns 216 on the wafer. At this time, as described with reference to FIGS. 8 and 9, the second inter-metal insulator 220 composed of an oxide is hardly etched. However, the metal film pattern 214 that is exposed due to the removal of the capping layer pattern 216 should not be over-etched. To obtain the fuse shown in FIG. 10, first, a second inter-metal insulator 220 composed of an oxide, a barrier metal layer pattern 212 composed of Ti/TiN, and a metal film pattern 214 composed of Al were sequentially deposited on a bare wafer. Then, the result was wet etched using a mixture of H₂O₂ and de-ionized water (DIW) in a volume ratio of 9:1 at room temperature for about 20 minutes. Then, images of a sectional view of the result are taken. As a result, referring to FIG. 10, before the wet etching, the sum of the heights of the barrier metal layer pattern 212 and the metal film pattern 214 are about 624.60 nm, 621.82 nm, and 628.76 nm. The heights vary depending on measured locations. After the wet etching, the sum of the heights of the barrier metal layer pattern 212 and the metal film pattern 214 measured at different points is about 591.29 nm, 587.12 nm, and 584.35 nm. In consideration of the above results, it is confirmed that the over-etching of the capping layer pattern 216 may not result in the over-etching of the metal layer pattern 212.

According to a method of forming a fuse in a semiconductor device according to an embodiment of the present invention, a dry etching process can be performed until a capping layer pattern is exposed, and a wet etching process can be performed to remove the capping layer pattern. As a result, an inter-metal insulator formed between adjacent metal film patterns may retain a sufficient height to reduce the likelihood that a short-circuit occurs between adjacent metal film patterns caused by fragments or the like generated by laser-cutting.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed:

1. A method of forming a fuse in a semiconductor device, the method comprising:
selectively removing an inter-metal insulator to expose a fuse capping layer by recessing the inter-metal insulator around the fuse; and
removing the capping layer from the fuse to expose a fuse metal film thereunder.

2. A method according to claim 1 wherein selectively removing an inter-metal insulator to expose a fuse capping layer by recessing the inter-metal insulator around the fuse further comprises:
selectively removing the inter-metal insulator to expose the fuse capping layer so that the capping layer protrudes from the inter-metal insulator around the fuse.

3. A method according to claim 1 wherein selectively removing comprises selectively dry-etching the inter-metal insulator relative the capping layer.

4. A method according to claim 1 wherein removing the capping layer comprises selectively wet-etching the capping layer relative to the inter-metal insulator around the fuse.

5. A method according to claim 4 wherein selectively wet-etching the capping layer relative to the inter-metal insulator around the fuse comprises selectively wet-etching the capping layer relative to the inter-metal insulator around the fuse to recess the fuse to beneath a surface of the inter-metal insulator around the fuse by about 1000 Angstroms.

6. A method according to claim 4 wherein the inter-metal insulator comprises an oxide and the capping layer comprises Ti, TiN, and/or Ti/TiN.

7. A method according to claim 4 wherein selectively wet-etching comprises wet-etching using an etching solution comprising H₂O₂ or a mixture of H₂O₂ and water.

8. A method according to claim 1 wherein the capping layer comprises Ti/TiN and a metal film thereunder comprises Al.

9. A method according to claim 4 wherein selectively wet-etching the capping layer relative to the inter-metal insulator around the fuse further comprises wet-etching using a solution of H₂O₂ at about 60 degrees Centigrade for about 11 minutes.

10. A method according to claim 9 wherein the solution of H₂O₂ further comprises a chemical solution that avoids etching of Ti and TiN.

11. A method according to claim 1 wherein removing the capping layer from the fuse to expose a fuse metal film thereunder further comprises wet-etching the capping layer to recess the fuse beneath a surface of the inter-metal insulator around the fuse to level sufficient to avoid contamination other fuses with debris from a laser cut of the fuse.

12. A method of forming a fuse in a semiconductor device, the method comprising:
selectively dry-etching an inter-metal insulator to expose a fuse capping layer by recessing the inter-metal insulator around the fuse; and
selectively wet-etching the capping layer relative to the inter-metal insulator around the fuse to recess the fuse to beneath a surface of the inter-metal insulator around the fuse by about 1000 Angstroms using an etching solution comprising H₂O₂ or a mixture of H₂O₂ and water.

13. A method of forming a fuse in a semiconductor device, the method comprising:
forming an interconnection layer pattern on a first inter-metal insulator formed on a semiconductor, the interconnection layer comprising a metal film pattern and a capping layer pattern to provide a fuse;
forming a second inter-metal insulator covering the metal film pattern and the capping layer pattern on the first inter-metal insulator;
etching the second inter-metal insulator to expose the capping layer pattern formed in a fuse opening region; and
wet-etching the exposed capping layer pattern to expose the metal film pattern.

14. A method according to claim 13 wherein the capping layer pattern comprises a material having a sufficient wet etch selectively with respect to the second inter-metal insulator.

15. A method according to claim 14 wherein the second inter-metal insulator comprises an oxide and the capping layer pattern comprises Ti, TiN, and/or Ti/TiN.

16. A method according to claim 13 wherein the wet-etching is performed using an etching solution comprising H₂O₂ or a mixture of H₂O₂ and water.

17. A method according to claim 13 wherein the capping layer pattern and the metal film pattern is composed of materials having a sufficient etch selectivity with respect to each other.

18. A method according to claim 17 wherein the capping layer pattern comprises Ti/TiN and the metal film pattern comprises Al.

19. A method according to claim 13 wherein wet-etching comprises selectively wet-etching the capping layer pattern relative to the second inter-metal insulator around the fuse to recess the fuse to beneath a surface of the inter-metal insulator around the fuse by about 1000 Angstroms using an etching solution comprising H₂O₂ or a mixture of H₂O₂ and water.
